(19) United States
(12) Patent Application Publication
(10) Pub. No.: US 2010/0102830 A1
(43) Pub. Date: Apr. 29, 2010

(54) Physical Force Capacitive Touch Sensor

(75) Inventors: Keith Curtis, Gilbert, AZ (US); Fanie Duvenhage, Phoenix, AZ (US)

Correspondence Address: King & Spalding LLP, 401 Congress Avenue, Suite 3200, Austin, TX, 78701, US

(73) Assignee: MICROCHIP TECHNOLOGY INCORPORATED, Chandler (AZ)

(21) Appl. No.: 12/556,191

(22) Filed: Sep. 9, 2009

Related U.S. Application Data
(60) Provisional application No. 61/108,648, filed on Oct. 27, 2008.

(51) Int. Cl. G01R 27/26; H03K 17/975

(52) U.S. Cl. 324/661; 200/600

(57) ABSTRACT

A physical force capacitive touch sensor comprises a capacitive sensor element on a substrate, a physically deformable electrically insulating spacer over the capacitive sensor element, and a conductive plane over the physically deformable electrically insulating spacer that is substantially parallel to the capacitive sensor element. The conductive plane is connected to a power supply common and/or grounded to form a capacitor with the capacitive sensor element and for improved shielding of the capacitive sensor element from electrostatic disturbances and false triggering thereof. A protective cover may be placed over the conductive plane to act as an environmental seal for improved physical and weather protection, but is not essential to operation of the capacitive touch sensor.

### RELATED PATENT APPLICATION

This application claims priority to commonly owned U.S. Provisional Patent Application Ser. No. 61/108,648; filed Oct. 27, 2008; entitled “Physical Force Capacitive Touch Sensor,” by Keith Curtis and Fanie Duvenhage; and is hereby incorporated by reference herein for all purposes.

### TECHNICAL FIELD

The present disclosure relates to electronic capacitive touch sensors, and more particularly, to a more secure capacitive touch sensor that requires physical force on the touch sensor during activation and further shields the sensor from extraneous unwanted activation by inadvertent proximity of a user.

### BACKGROUND

Capacitive touch sensors are used as a user interface to electronic equipment, e.g., calculators, telephones, cash registers, gasoline pumps, etc. The capacitive touch sensors are activated (controls a signal indicating activation) by a change in capacitance of the capacitive touch sensor when an object, e.g., user finger tip, causes the capacitance thereof to change. Referring to FIG. 1, depicted is a prior technology capacitive touch sensor generally represented by the numeral 100. The prior technology capacitive touch sensor 100 comprises a substrate 102, a sensor element 112 and a protective covering 108, e.g., glass. When a user finger tip 110 comes in close proximity to the sensor element 112, the capacitance value of the sensor element 112 changes. This capacitance change is electronically processed (not shown) so as to generate a signal indicating activation of the capacitive touch sensor 100 by the user (only finger tip 110 thereof shown). The protective covering 108 may be used to protect the sensor element 112 and for marking of the sensor 100.

Problems exist with proper operation of the sensor 100 that may be caused by water, oil, mud, and/or food products, e.g., ketchup and mustard, either false triggering activation or inhibiting a desired activation thereof. Also problems exist when metallic objects (not shown) come in near proximity of the sensor element 112 and cause an undesired activation thereof. When there are a plurality of sensors 100 arranged in a matrix, e.g., numeric and/or pictorial arrangement, activation of an intended one of the sensors 100 may cause a neighbor sensor(s) 100 to undesirably actuate because of the close proximity of the user finger tip 110, or other portion of the user hand (not shown). This multiple activation of more then one sensor 100 may be caused when touching the intended sensor 100 and a portion of the user's hand also is sufficiently close to adjacent neighbor sensors 100 for activation thereof.

### SUMMARY

The aforementioned problems are solved, and other and further benefits achieved by the capacitive touch sensor disclosed herein. According to the teachings of this disclosure, a capacitive touch sensor comprises a capacitive sensor element on a substrate, a physically deformable electrically insulating spacer over the capacitive sensor element, and a conductive plane over the physically deformable electrically insulating spacer that is substantially parallel to the capacitive sensor element. The conductive plane is connected to a power supply common and/or grounded to form a capacitor with the capacitive sensor element and for improved shielding of the capacitive sensor element from electrostatic and electromagnetic disturbances, and false triggering thereof. A protective cover may be placed over the conductive plane to act as an environmental seal for improved physical and weather protection, but is not essential to operation of the capacitive touch sensor.

When the user presses down onto the approximate center of a target (e.g., alpha/numeric and/or graphical) on the conductive plan of the capacitive touch sensor, the distance between the capacitive sensor element and the conductive plane is reduced, thus changing the capacitance of the capacitive sensor element. A capacitance change detection circuit monitors the capacitance value of the capacitive sensor element, and when the capacitance value changes (e.g., increases) a sensor activation signal is generated.

The capacitive touch sensor, according to the teachings of this disclosure, is substantially immune to false triggering caused by a user in close proximity to the sensor target because a correct area of the conductive plane must be slightly deformed in order for the capacitance of the capacitive sensor element to change. In addition, stray metallic objects will not substantially affect the capacitance of the capacitive sensor element for the same reason. Furthermore the assembly of the capacitive touch sensor can be sealed with the physically deformable electrically insulated spacer and may thus be substantially immune to liquid contamination thereof.

According to a specific example embodiment of this disclosure, a physical force capacitive touch sensor comprises: a substrate; a capacitive sensor element on a face of the substrate; a deformable spacer covering the capacitive sensor element; a substantially non-deformable spacer surrounding the capacitive sensor element and the deformable spacer; and a electrically conductive plane covering the deformable spacer and the substantially non-deformable spacer, wherein when a mechanical force is applied to the electrically conductive plane biased toward the capacitive sensor element, the capacitive sensor element changes capacitance.

According to another specific example embodiment of this disclosure, a user interface having a plurality of physical force capacitive touch sensors comprises: a substrate; a plurality of capacitive sensor elements on a face of the substrate; deformable spacers covering the plurality of capacitive sensor elements; a substantially non-deformable spacer surrounding the plurality of capacitive sensor elements and the deformable spacers; and a electrically conductive plane covering the deformable spacers and the substantially non-deformable spacer, wherein when a mechanical force is applied to the electrically conductive plane biased toward a one of the plurality of capacitive sensor elements, the one of the plurality of capacitive sensor elements changes capacitance.

### BRIEF DESCRIPTION OF THE DRAWINGS

A more complete understanding of the present disclosure thereof may be acquired by referring to the following description taken in conjunction with the accompanying drawings wherein:

FIG. 1 is a schematic side view of a cross section of a prior technology capacitive touch sensor.

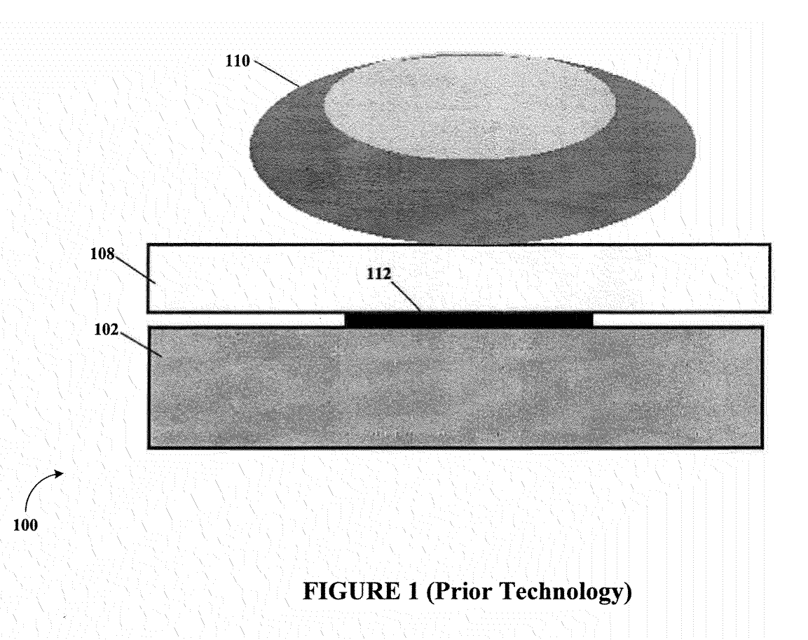

FIG. 2 is a schematic side view of a cross section of a capacitive touch sensor, according to a specific example embodiment of this disclosure; and

FIG. 3 is a schematic plan view of a user interface arranged as data input matrix and having a plurality of capacitive touch sensors as shown in FIG. 2.

While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein, but on the contrary, this disclosure is to cover all modifications and equivalents as defined by the appended claims.

### DETAILED DESCRIPTION

Referring now to the drawings, the details of an example embodiment is schematically illustrated. Like elements in the drawings will be represented by like numbers, and similar elements will be represented by like numbers with a different lower case letter suffix.

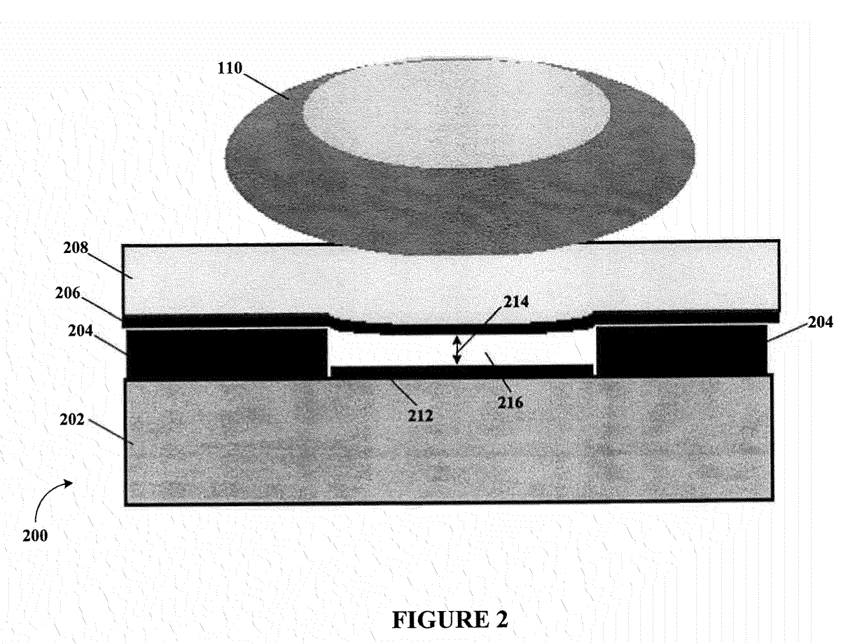

Referring to FIG. 2, depicted is a schematic side view of a cross section of a capacitive touch sensor, according to a specific example embodiment of this disclosure. The capacitive touch sensor, generally represented by the numeral 200, comprises a substrate 202, a capacitive sensor element 212, a deformable spacer 216, non-deformable spacers 204, a conductive plane 206 and a protective cover 208. The conductive plane 206 is connected to a power supply common and/or grounded (not shown) to form a capacitor with the capacitive sensor element 212 and for improved shielding of the capacitive sensor element 212 from electrostatic disturbances and false triggering thereof The protective cover 208 may be used as an environmental seal for improved physical and weather protection, but is not essential to operation of the capacitive touch sensor 200.

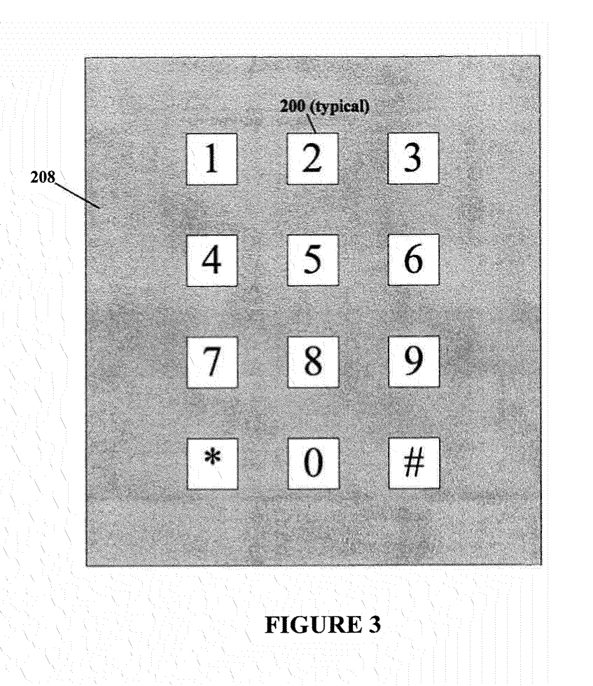

The conductive plane 206 and protective cover 208 are physically deformable over the deformable spacer 216 so that when a user finger 110 presses down onto the approximate center of a target (e.g., alpha/numeric and/or graphical see FIG. 3) on the conductive plan 206 of the capacitive touch sensor 200, the distance 214 between the capacitive sensor element 212 and the conductive plane 206 is reduced, thus changing the capacitance of the capacitive sensor element 212. A capacitance change detection circuit (not shown) monitors the capacitance value of the capacitive sensor element 212, and when the capacitance value changes (e.g., increases) a sensor activation signal is generated (not shown).

The capacitive touch sensor 200 is substantially immune to false triggering caused by a user in close proximity to the sensor target because a correct area of the conductive plane 206 must be slightly deformed in order for the capacitance of the capacitive sensor element 212 to change, e.g., requires an actuation force from the user finger 110. In addition, stray metallic objects will not substantially affect the capacitance of the capacitive sensor element 212 for the same reason. Furthermore the assembly of the capacitive touch sensor 200 can be sealed with the physically deformable electrically insulated spacer 216 and may thus be substantially immune to liquid contamination thereof. Also since the non-deformable spacers 204 surround the capacitive sensor element 212 and the physically deformable electrically insulated spacer 216, adjacent capacitive sensor elements 212 (see FIG. 3) will not be affected, e.g., no capacitance change because areas of conductive plane 206 over adjacent capacitive sensor elements 212 will not be deformed.

The capacitive sensor element 212 is electrically conductive and may be comprised of metal such as, for example but not limited to, copper, aluminum, silver, gold, tin, and/or any combination thereof, plated or otherwise. The capacitive sensor element 212 may also be comprised of non-metallic conductive material. The substrate 202 and capacitive sensor element 212 may be, for example but are not limited to, a printed circuit board having conductive metal areas etched thereon, a ceramic substrate with conductive metal areas plated thereon, etc.

Referring to FIG. 3, depicted is a schematic plan view of a user interface arranged as data input matrix and having a plurality of capacitive touch sensors as shown in FIG. 2. A plurality of capacitive touch sensors 200 are arranged in a matrix and have alpha-numeric representations indicating the functions thereof. When a mechanical force is applied any one of the capacitive touch sensors 200, the area directly over the capacitive sensor element 212 of that one capacitive touch sensor 200 will be deformed toward the direction of the mechanical force, bring the conductive plane 206 closer to the capacitive sensor element 212 and thereby changing the capacitance thereof.

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and function, as will occur to those ordinarily skilled in the pertinent art and having the benefit of this disclosure. The depicted and described embodiments of this disclosure are examples only, and are not exhaustive of the scope of the disclosure.

What is claimed is:

1. A physical force capacitive touch sensor, comprising:
a substrate;
a capacitive sensor element on a face of the substrate;
a deformable spacer covering the capacitive sensor element;
a substantially non-deformable spacer surrounding the capacitive sensor element and the deformable spacer; and
a electrically conductive plane covering the deformable spacer and the substantially non-deformable spacer,
wherein when a mechanical force is applied to the electrically conductive plane biased toward the capacitive sensor element, the capacitive sensor element changes capacitance.

2. The physical force capacitive touch sensor according to claim 1, wherein the electrically conductive plane is connected to a power supply common.

3. The physical force capacitive touch sensor according to claim 1, wherein the electrically conductive plane is connected to ground.

4. The physical force capacitive touch sensor according to claim 1, further comprising a protective cover over the electrically conductive plane.

5. The physical force capacitive touch sensor according to claim 4, wherein the protective cover comprises a flexible glass.

6. The physical force capacitive touch sensor according to claim 4, wherein the protective cover comprises a flexible plastic.

7. The physical force capacitive touch sensor according to claim 1, wherein the substrate is a printed circuit board and the capacitive sensor element is an electrically conductive area on the face of the printed circuit board.

8. The physical force capacitive touch sensor according to claim 1, wherein the substrate is a ceramic substrate and the capacitive sensor element is an electrically conductive area on the face of the ceramic substrate.

9. A user interface having a plurality of physical force capacitive touch sensors, said user interface comprising:
a substrate;
a plurality of capacitive sensor elements on a face of the substrate;
deformable spacers covering the plurality of capacitive sensor elements;
a substantially non-deformable spacer surrounding the plurality of capacitive sensor elements and the deformable spacers; and
a electrically conductive plane covering the deformable spacers and the substantially non-deformable spacer,
wherein when a mechanical force is applied to the electrically conductive plane biased toward a one of the plurality of capacitive sensor elements, the one of the plurality of capacitive sensor elements changes capacitance.

10. The user interface according to claim 9, wherein the electrically conductive plane is connected to a power supply common.

11. The user interface according to claim 9, wherein the electrically conductive plane is connected to ground.

12. The user interface according to claim 9, further comprising a protective cover over the electrically conductive plane.
